(19) United States
(12) Patent Application Publication
(10) Pub. No.: US 2013/0320427 A1
(43) Pub. Date: Dec. 5, 2013

(54) GATED CIRCUIT STRUCTURE WITH SELF-ALIGNED TUNNELING REGION

(71) Applicants: Wei-Yip LOH, Austin, TX (US); Richard HILL, Austin, TX (US); Prashant MAJHI, Austin, TX (US)

(72) Inventors: Wei-Yip LOH, Austin, TX (US); Richard HILL, Austin, TX (US); Prashant MAJHI, Austin, TX (US)

(73) Assignee: SEMATECH, INC., Albany, NY (US)

(21) Appl. No.: 13/487,627

(22) Filed: Jun. 4, 2012

(51) Int. Cl. H01L 29/78; H01L 21/283

(52) U.S. Cl. 257/327; 438/585; 257/E29.262; 257/E21.19

(57) ABSTRACT

A tunnel field-effect transistor is provided, which includes a fin-shaped, source-drain circuit structure with a source region and a drain region. The circuit structure is angled in cross-sectional elevation, and includes a first portion and a second portion. The first portion extends away from the second portion, and the source region is disposed in the first or second portion, and the drain region is disposed in the other of the first or second portion. The transistor further includes a gate electrode for gating the circuit structure and a self-aligned tunneling region. The tunneling region is self-aligned to at least a portion of the circuit structure and extends between the gate electrode and the first or second portion of the fin-shaped circuit structure, and the self-aligned tunneling region is at least partially disposed in parallel, spaced opposing relation to a control surface of the gate electrode.

### BACKGROUND

This invention relates generally to semiconductor devices, and to processes for making semiconductor devices, and more particularly, to tunnel field-effect transistors and methods of making the same.

The sizes of microelectronic devices and other active and passive electrical components are continuously scaled down in attempts to increase device integrated-circuit density. Field-effect transistors are fabricated to provide logic and data-processing functions, among others, for the microelectronic devices built on a wafer. Typically, lithography techniques are used to define the sizes of the field-effect transistors in the devices. As microelectronic device size is continually scaled down, process challenges may increase.

### BRIEF SUMMARY

The present invention relates, in one aspect, to a semiconductor device which includes a gated circuit structure. The gated circuit structure comprises an angled circuit structure, a gate electrode, and a self-aligned tunneling region. The angled circuit structure is at least partially angled in cross-sectional elevation, and includes a first portion and a second portion. The first portion of the angled circuit structure extends away from the second portion of the angled circuit structure. The self-aligned tunneling region is self-aligned to at least a portion of the fin-shaped circuit structure and extends between the gate electrode and at least one of the first portion or the second portion of the angled circuit structure, and a tunneling surface of the self-aligned tunneling region is disposed at least partially parallel to a surface of the gate electrode.

In another aspect, a tunnel field-effect transistor is provided which comprises a source-drain stack structure, a gate electrode for gating the source-drain stack structure, and a self-aligned tunneling region. The stack structure includes a source region and a drain region, and is at least partially angled in cross-sectional elevation. The source-drain stack structure comprises a first portion and a second portion, with the first portion extending away from the second portion. The source region is disposed in one of the first portion or the second portion, and the drain region is disposed in the other of the first portion or the second portion. The self-aligned tunneling region is self-aligned to at least a portion of the source-drain stack structure and extends between the gate electrode and at least one of the first portion or the second portion of the source-drain stack structure. A tunneling surface of the self-aligned tunneling region is disposed at least partially parallel to a surface of the gate electrode.

In a further aspect, a method of fabricating a semiconductor device is provided. The method includes fabricating a gated circuit structure, wherein fabricating the gated circuit structure comprises: providing an angled circuit structure, the angled circuit structure being at least partially angled in cross-sectional elevation, and comprising a first portion and a second portion, the first portion of the angled circuit structure extending away from the second portion of the angled circuit structure; and providing a self-aligned tunneling region and a gate electrode for the angled circuit structure, the self-aligned tunneling region being self-aligned to at least a portion of the angled circuit structure and extending between the gate electrode and at least one of the first portion or the second portion of the angled circuit structure, and a tunneling surface of the self-aligned tunneling region being at least partially disposed parallel to a surface of the gate electrode.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 is a cross-sectional elevational view of a conventional tunnel field-effect transistor;

FIG. 2 is a cross-sectional elevational view of one embodiment of a semiconductor device, and more particularly, a tunnel field-effect transistor, in accordance with one or more aspects of the present invention;

FIG. 3A is a plan view of one embodiment of a structure attained during fabrication of a semiconductor device, in accordance with one or more aspects of the present invention;

FIG. 3B is a cross-sectional elevational view of the structure of FIG. 3A, taken along line 3B-3B thereof, in accordance with one or more aspects of the present invention;

FIG. 4A is a plan view of the structure of FIGS. 3A & 3B, after source or drain layer formation, in accordance with one or more aspects of the present invention;

FIG. 4B is a cross-sectional elevational view of the structure of FIG. 4A, taken along line 4B-4B thereof, in accordance with one or more aspects of the present invention;

FIG. 5A is a plan view of the structure of FIGS. 4A & 4B, after mesa formation, in accordance with one or more aspects of the present invention;

FIG. 5B is a cross-sectional elevational view of the structure of FIG. 5A, taken along line 5B-5B thereof, in accordance with one or more aspects of the present invention;

FIG. 6A is a plan view of the structure of FIGS. 5A & 5B, after fin definition, and exposure of a portion of the source or drain region, in accordance with one or more aspects of the present invention;

FIG. 6B is a cross-sectional elevational view of the structure of FIG. 6A, taken along line 6B-6B thereof, in accordance with one or more aspects of the present invention;

FIG. 7A is a plan view of the structure of FIGS. 6A & 6B, and illustrates one embodiment of source region formation, in accordance with one or more aspects of the present invention;

FIG. 7B is a cross-sectional elevational view of the structure of FIG. 7A, taken along line 7B-7B thereof, in accordance with one or more aspects of the present invention;

FIG. 8A is a plan view of the structure of FIGS. 7A & 7B, and illustrates formation of a self-aligned tunneling region, in accordance with one or more aspects of the present invention;

FIG. 8B is a cross-sectional elevational view of the structure of FIG. 8A, taken along line 8B-8B thereof, in accordance with one or more aspects of the present invention;

FIG. 9A is a plan view of the structure of FIGS. 8A & 8B, after gate formation, in accordance with one or more aspects of the present invention;

FIG. 9B is a cross-sectional elevational view of the structure of FIG. 9A, taken along line 9B-9B thereof, in accordance with one or more aspects of the present invention;

FIG. 9C is a plan view of the structure of FIGS. 8A & 8B, after gate formation and over-etching of the gate stack down through the tunneling region, in accordance with one or more aspects of the present invention;

FIG. 9D is a cross-sectional elevational view of the structure of FIG. 9C, taken along line 9D-9D thereof, in accordance with one or more aspects of the present invention;

FIG. 9E is a cross-sectional elevational view of the structure of FIG. 9C, taken along line 9E-9E thereof, in accordance with one or more aspects of the present invention;

FIG. 10A is a plan view of the structure of FIGS. 9A & 9B, after formation of electrical contacts to the drain, source and gate regions of the semiconductor device, in accordance with one or more aspects of the present invention;

FIG. 10B is a cross-sectional elevational view of the structure of FIG. 10A, taken along line 10B-10B thereof, in accordance with one or more aspects of the present invention;

FIG. 10C depicts an alternate embodiment of the gated circuit structure of FIGS. 10A & 10B, wherein the source and drain regions are reversed, in accordance with one or more aspects of the present invention;

FIG. 11 depicts a cross-sectional elevational view of one embodiment of a gated circuit structure, in accordance with one or more aspects of the present invention;

FIG. 12A is a cross-sectional elevational view of an alternate embodiment of a semiconductor device, and more particularly, an alternate embodiment of a tunnel field-effect transistor, in accordance with one or more aspects of the present invention;

FIG. 12B is an enlarged depiction of a portion of the semiconductor device of FIG. 12A, taken along line 12B, and illustrates carrier flow through the self-aligned tunneling region of the semiconductor device, in accordance with one or more aspects of the present invention;

FIG. 13 is a cross-sectional elevational view of another embodiment of a semiconductor device, or tunnel field-effect transistor, in accordance with one or more aspects of the present invention; and

FIG. 14 depicts one embodiment of a flow diagram of a design process which may be employed in semiconductor design and manufacture of semiconductor structures, in accordance with one or more aspects of the present invention.

### DETAILED DESCRIPTION

Generally stated, disclosed herein is a semiconductor device comprising a gated circuit structure, and a method of fabrication thereof. The gated circuit structure, which in one embodiment is a tunnel field-effect transistor (TFET), includes an angled circuit structure (such as a fin-shaped circuit structure or an L-shaped circuit structure), a gate electrode associated with the angled circuit structure, and a self-aligned tunneling region. The angled circuit structure is, in one embodiment, at least partially angled in cross-sectional elevation, and includes a first and second portion, with the first portion of the angled circuit structure extending away from the second portion thereof, for example, at a right angle. The self-aligned tunneling region is self-aligned to at least a portion of the angled circuit structure, and extends between the gate electrode and at least one of the first portion or the second portion of the angled circuit structure. Further, the self-aligned tunneling region extends, and a tunneling surface thereof is disposed, at least partially, in parallel, spaced opposing relation to a surface (e.g., control surface) of the gate electrode. Various embodiments and methods of manufacture of such a gated circuit structure are described hereinbelow with reference to FIGS. 2-13.

In one embodiment, the gated circuit structure disclosed herein utilizes novel characteristics of the edge of a semiconductor structure, such as a fin, to selectively form a doped layer on (for example) the horizontal surface of the structure to define a horizontally-extending tunneling pocket. In other embodiments, conformal deposition or epitaxial growth may be employed to define a vertically-extending tunneling pocket self-aligned to the fin, as described further herein. In certain embodiments described herein, the tunneling (or junction) pocket resides primarily next to the source region of the TFET, and comprises a region of opposite dopant to the source region so as to enhance the tunneling probability of carriers from the source region to the pocket region. Advantageously, in certain embodiments, selective doping of only the pocket region while avoiding the channel region using (for example) the edge of the semiconductor fin structure, provides self-alignment of the tunneling source region to the channel. This self-alignment is achieved without precise lithography techniques and complex alignment schemes. Disclosed herein are thus various gated circuit structures which employ, by way of example, a fin-like structure to define a tunnel FET which incorporates such a self-aligned tunneling region. The resultant self-aligned structure may be employed for various semiconductor devices, such as tunnel devices, memory devices, high-powered devices, etc.

Reference is made below to the drawings, which are not drawn to scale to facilitate an ease of understanding, wherein the same reference numbers used throughout different figures designate the same or similar elements.

Conventional tunnel devices typically exhibit poor drive current due to a low tunneling probability and/or poor electrostatic coupling to the gate. A vertical pocket device may increase the gate coupling and minimize lateral drain field effects, but typically involves significant process complexity. Planar pockets, with a tunneling pocket next to the channel, pose significant process challenges, and typically involve difficult alignment processes.

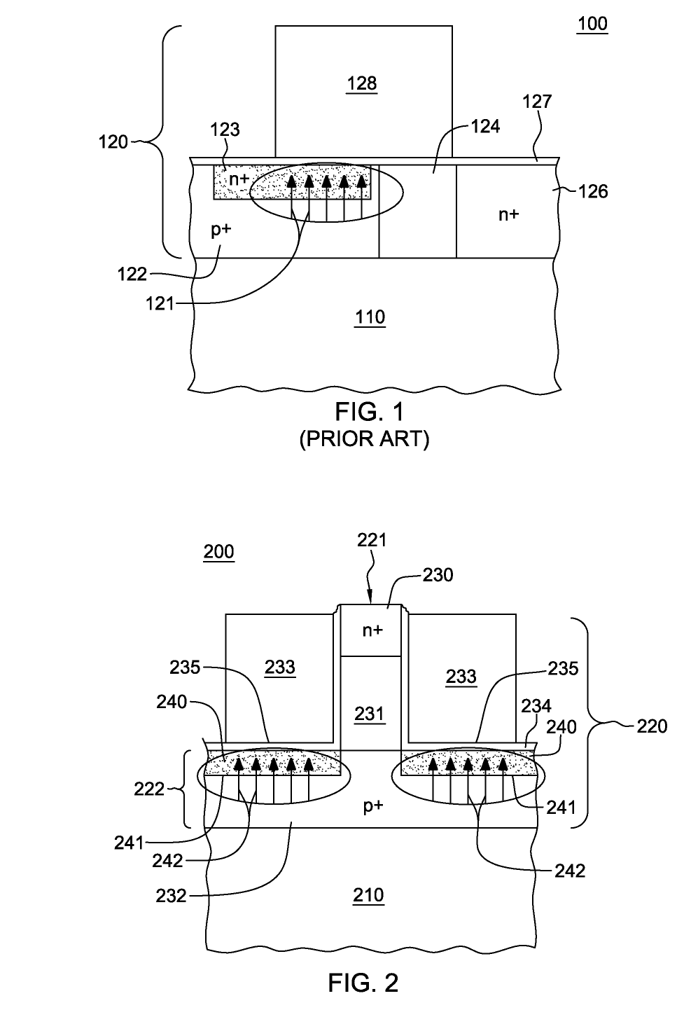

By way of example, FIG. 1 depicts a conventional semiconductor device 100 comprising a tunnel field-effect transistor 120 disposed over an isolation region 110, such as a buried oxide (BOX). The tunnel field-effect transistor (TFET) includes, in the depicted embodiment, a p+ source region 122, an intrinsic region 124, an n+ drain region 126, and a gate 128 disposed over the source and intrinsic regions 122, 124. An n+ tunneling region 123 is provided within source region 122, and gate region 128 is separated from the source and drain regions via a gate dielectric 127. When gated ON, carriers 121 flow from the source region 122 to the tunneling region 123, and subsequently to the drain region 126.

The semiconductor device of FIG. 1 comprises a planar circuit structure, wherein the source and drain regions are in a common plane. This arrangement is ideal for MOSFET formation, but makes formation of the tunneling pocket difficult and complex. In particular, formation of the tunneling pocket in a planar TFET such as depicted in FIG. 1 requires use of a hard block mask and an overlap of the pocket to the gate defined by an overlap margin of the gate mask to the block mask. This is highly dependent on alignment and lithography capabilities. Even small misalignments can cause significant differences in device characteristics.

In comparison, disclosed herein is a gated circuit structure that comprises an angled tunnel field-effect transistor, which advantageously can be fabricated using a simplified set of processing steps, and which achieves enhanced operational benefits over a conventional planar TFET such as depicted in FIG. 1. In certain devices disclosed herein, L-shaped devices, with a tunneling pocket oriented perpendicular to the channel are provided, which form a perfect anisotropy between the channel and the tunneling pocket, allowing for ready application of self-aligned pocket formation using a variety of methods (such as described herein).

By way of example, FIG. 2 depicts one embodiment of a semiconductor device, generally denoted 200, comprising an angled circuit structure 220 fabricated, for example, over an isolation region 210, such as a BOX layer or substrate. In the depicted embodiment, the angled circuit structure comprises a novel TFET which has a fin-shaped or at least partial L-shaped elevational cross-section, with a first portion 221, and a second portion 222. In the depicted embodiment, first portion 221 extends substantially perpendicular from second portion 222. By way of example, an n+ drain region 230 and an intrinsic region 231 reside within first portion 221 of angled circuit structure 220, and a p+ source region 232 resides within second portion 222 of the angled circuit structure. A gate or gate electrode 233 is associated with the angled circuit structure, and separated from the first and second portions 221, 222 via a gate dielectric 234.

In the embodiment of FIG. 2, an n+, self-aligned, horizontally-oriented tunneling region 240 is provided within source region 232 of the angled circuit structure 220. This self-aligned tunneling region 240 is self-aligned to a portion of the angled circuit structure, that is, to the first portion 221 of the circuit structure. As illustrated, self-aligned tunneling region 240 is disposed at least partially in spaced opposing relation to a control surface 235 of gate electrode 233, and has a tunneling surface front 241 oriented parallel to the control surface 235 of the gate electrode. In operation, when gated ON carriers 242 pass from the p+ source region 232 into the n+ tunneling region 240, and from the tunneling region through the intrinsic region 231 into drain region 230. Advantageously, the tunnel field-effect transistor disclosed herein and depicted, by way of example in FIG. 2, may be employed at very low voltage since there is substantially no leakage current.

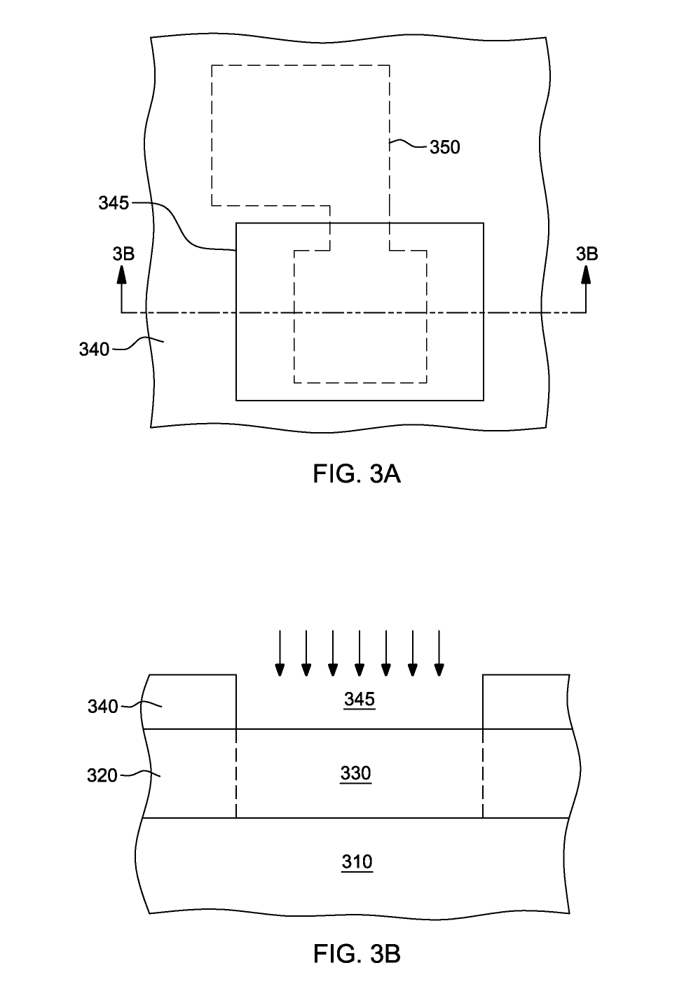

FIGS. 3A-10B depict one embodiment for fabricating an angled circuit structure similar to that depicted in FIG. 2.

FIGS. 3A & 3B depict an intermediate semiconductor structure wherein a semiconductor layer 320 is provided over an isolation region 310, such as a BOX layer or substrate. Semiconductor layer 320 may comprise, for example, epitaxial-grown Ge or Si (IV) or III-V silicon-on-oxide (SIO). As illustrated window 345 has been patterned in a photoresist 340 disposed over semiconductor layer 320. Window 345 exposes a region 330 that is to comprise, in one example, the source region of the circuit structure such as disclosed herein. As depicted in FIG. 3B, the patterned semiconductor layer 320 is subjected to an isolation implant, such as an Fe implant for III-V semiconductor material, which is a typical process used in a III-V fabrication process to pin the Fermi level of the region to the mid-gap so as to lower its conductivity. The iron implant forms an isolation region for the pad to not leak into the substrate. As illustrated by dashed lines in FIG. 3A, a mesa 350 is yet to be defined.

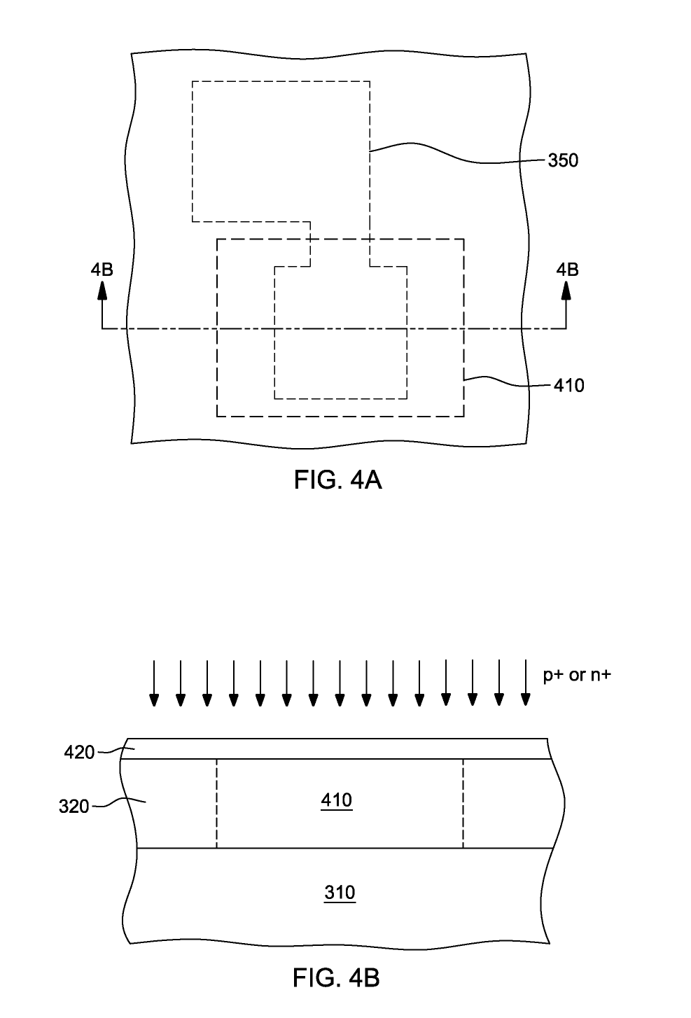

FIGS. 4A & 4B depict the structure of FIGS. 3A & 3B, and illustrate one process embodiment for drain formation, wherein a doped layer 420 is formed over the structure, including over undoped source region 410 of semiconductor layer 320. By way of example, blanket implant/anneal, or MBE, or MOCVD n+/p+ epitaxial growth may be employed in forming layer 420. For instance, the structure may be subjected to a blanket implant and thermal anneal or a blanket, in situ doped epitaxial layer growth to form the n+ or p+ drain of the tunnel field-effect transistor. This is a highly doped region, for example, with a doped concentration >10¹⁹/cm³, to facilitate forming ohmic contact to the resultant device.

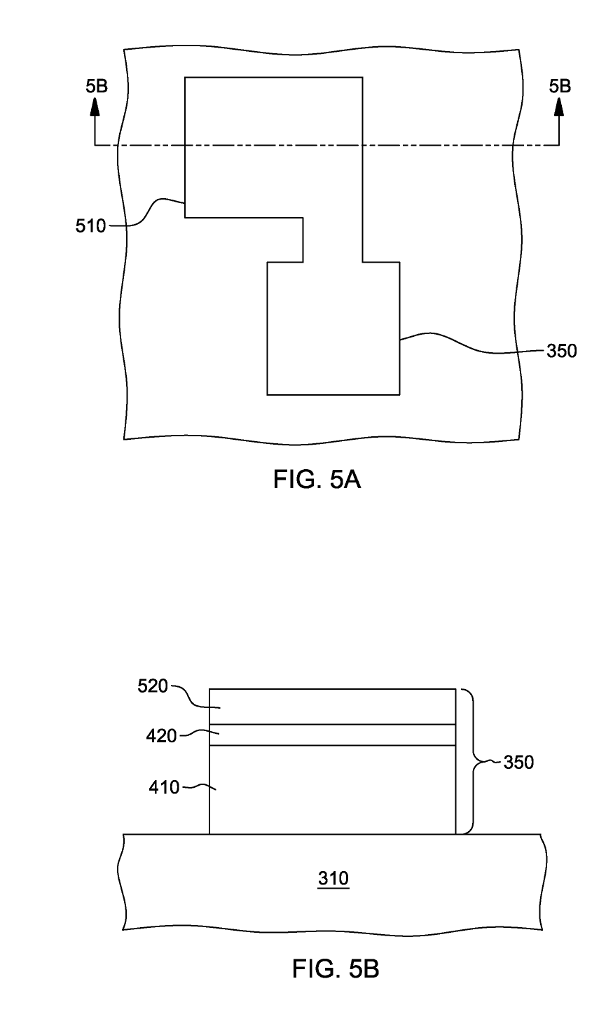

FIGS. 5A & 5B depict the semiconductor structure after mesa 350 formation. This may be accomplished by depositing on the wafer a hard mask 520, such as a silicon oxide hard mask, which is then patterned into a pattern 510, such as illustrated in FIG. 5A. Plasma etching of the doped layer 420 and undoped layer 410 is then performed down to the isolation region 310, resulting in the structure illustrated in FIG. 5B, with a mesa (or island) 350 shown above isolation region 310.

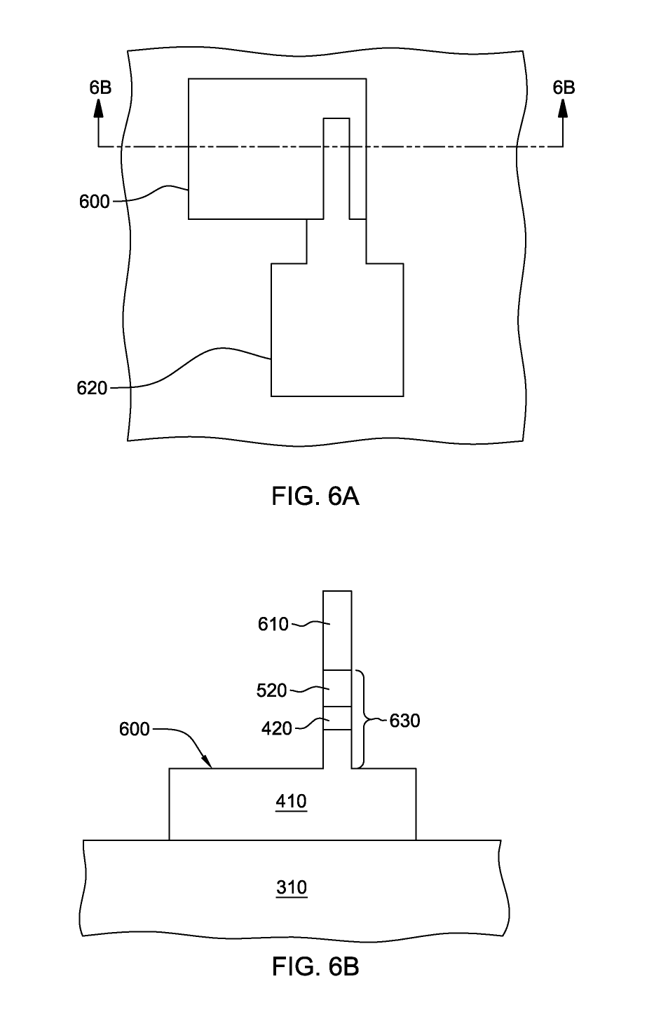

In FIGS. 6A & 6B, a structure is depicted which is obtained from the structure of FIGS. 5A & 5B after fin definition via lithography patterning and partial plasma etching. This process, in addition to defining a fin 630, also exposes portions 600 of the undoped semiconductor layer 410, which will subsequently facilitate forming (in one embodiment) the source region of the semiconductor device. As shown, a photoresist 610 has been deposited and patterned in the shape of a drain region 620 with fin 630 extending, by way of example, perpendicularly away from the undoped region 410.

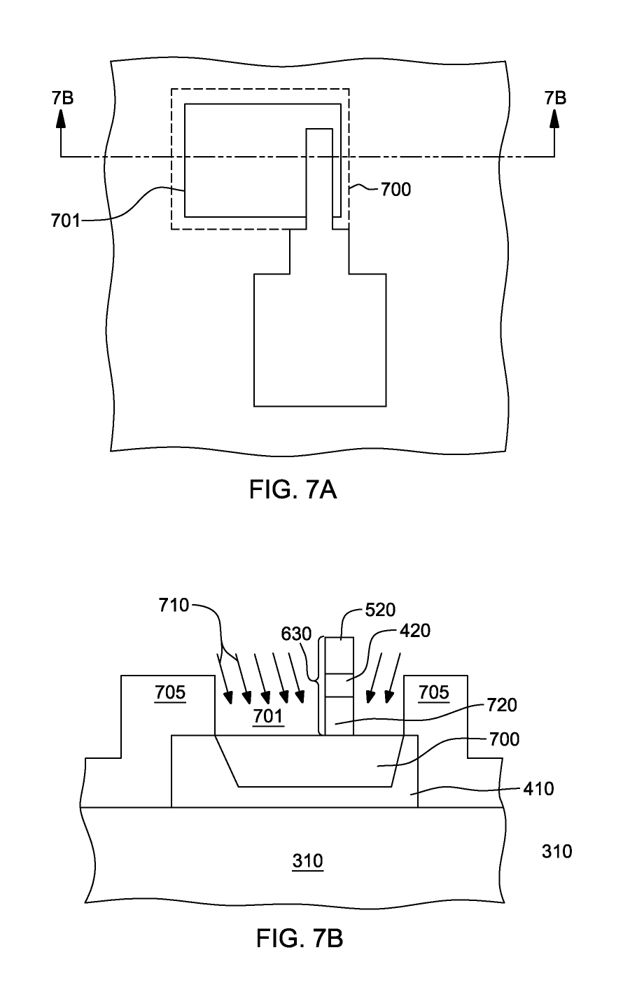

FIGS. 7A & 7B depict the structure of FIGS. 6A & 6B after deposition and patterning of a photoresist 705 to obtain an opening 701 through which source region 700 may be formed. In one embodiment, source formation utilizes an angled implant 710. Note that using an angled implant may result in a portion (not shown) of source region 700 directly under fin 630 remaining undoped. As an alternative process, source region 700 could have been formed previously by, for example, growing a doped region within or on the undoped semiconductor layer 410. After forming the source region 700, chemical mesa stripping may be employed to remove photoresist 705. Note that this process also results in defining an intrinsic region 720 within the fin 630 of the angled circuit structure.

Next, a self-aligned tunneling region 800 is formed, for example, utilizing a vertical ion implant 801 into source region 700 (as well as the exposed undoped region 410). In this example, the tunneling region 800 is self-aligned to the fin 630 of the semiconductor structure (covered by the hard mask 520), via the vertical implant of ions or carriers 801 into source region 700 (and undoped region 410). Note that operation of the resultant device is unaffected by extension of the self-aligned tunneling region 800 into the undoped region 410. If desired, lithography could be employed to limit the self-aligned tunneling region to the source region. The resultant tunneling region 800 (or pocket) may be, in one embodiment, less than or equal to 10 nanometers in thickness in a direction into source region 700. As one specific example, the tunneling region 800 may have a thickness of approximately 7 nanometers.

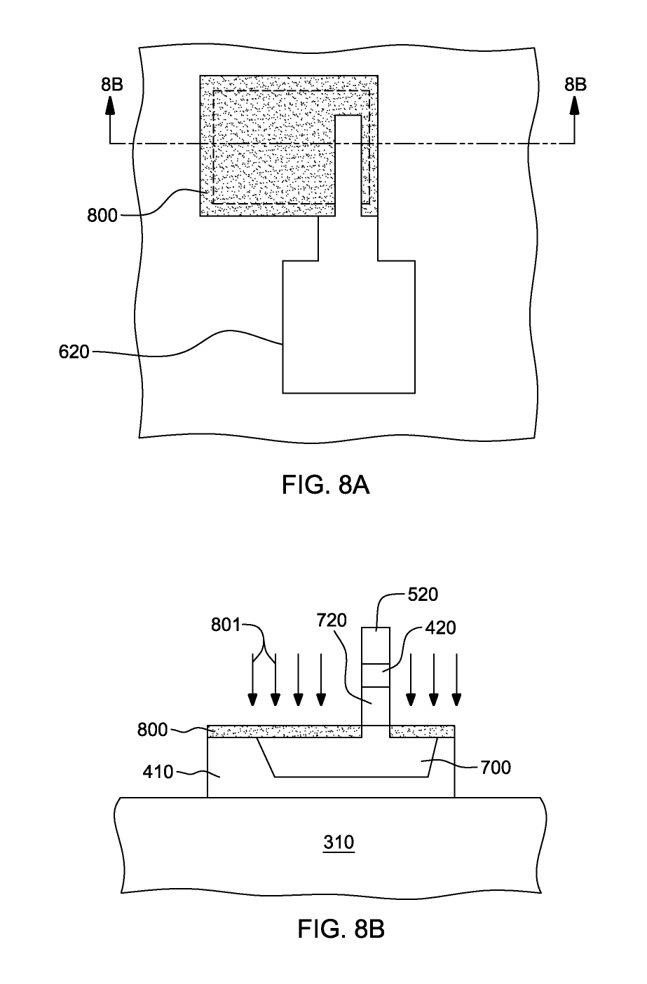

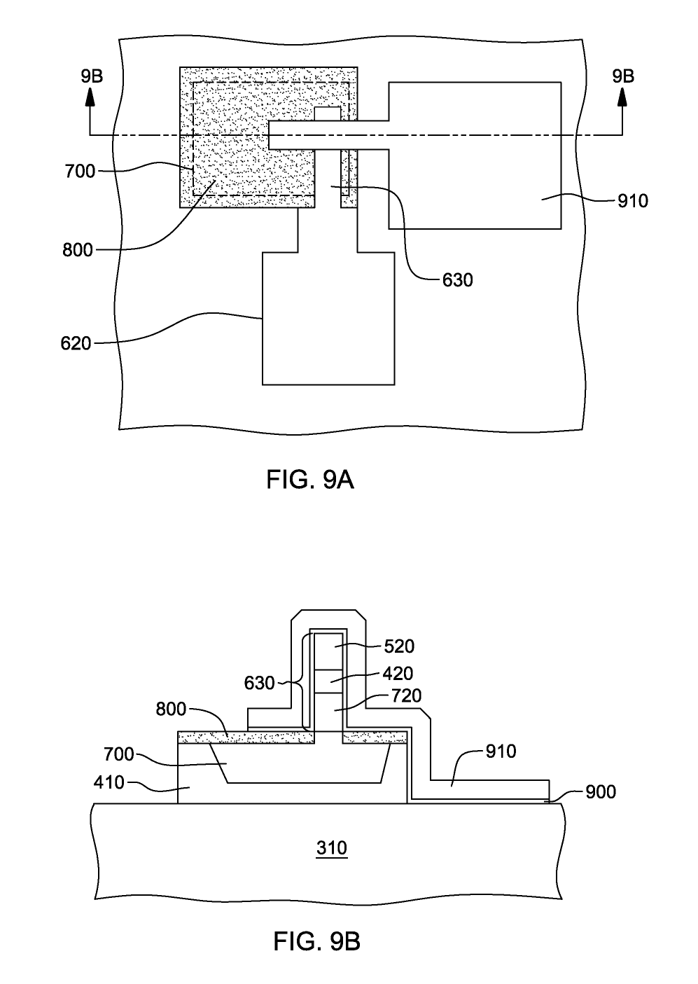

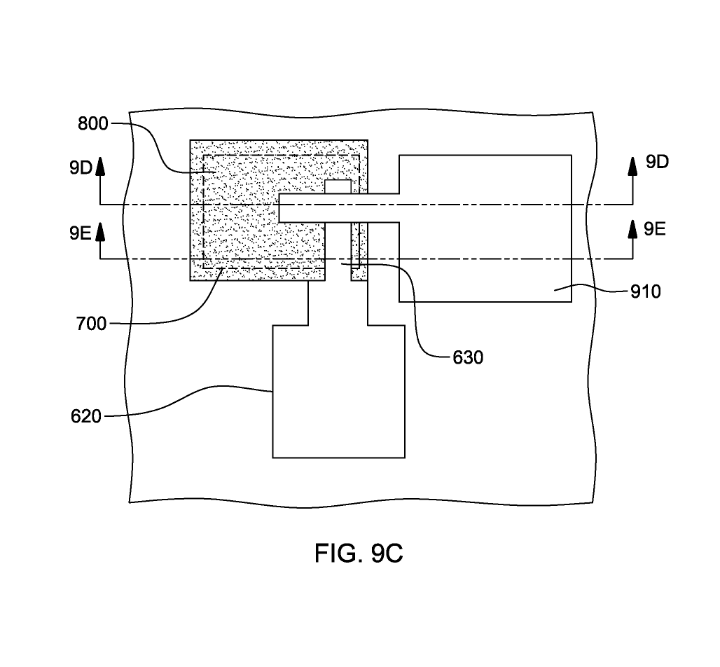

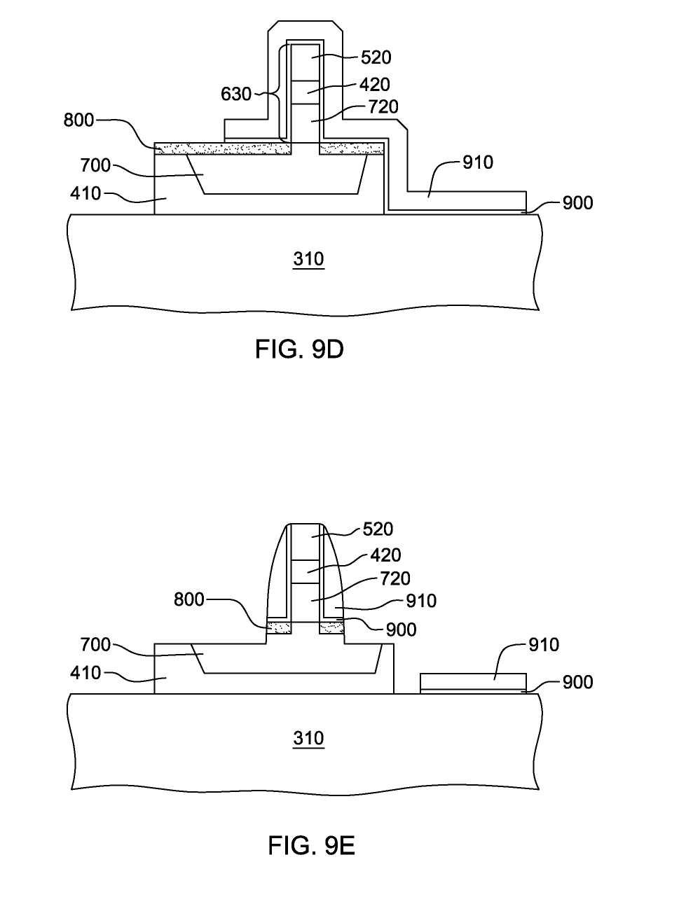

FIGS. 9A & 9B depict the semiconductor structure of FIGS. 8A & 8B after formation of a gate electrode 910. As illustrated, gate formation includes providing a gate dielectric 900 and then a gate electrode 910, which may comprise, for example, polysilicon, metal or other conductor. As depicted in FIGS. 9A & 9B, in one embodiment, the gate is formed to wrap around and over fin 630 so as to reside over a portion of the source region 700 and the self-aligned tunneling region 800, as well as a portion of drain region 420 and intrinsic region 720. In operation, a voltage applied to the gate electrode modulates the Fermi level of the self-aligned tunneling region 800 to either allow or disallow carrier tunneling from source region 700 into self-aligned tunneling region 800 during ON/OFF states, respectively. Note that in this configuration, where the self-aligned tunneling region comprises a horizontally-extending tunneling pocket, the gate is not truly self-aligned. In alternate implementations, however, where the self-aligned tunneling region comprises a vertically-extending tunneling pocket, then the gate is also self-aligned to the tunneling region, for example, via the fin-shaped structure. Note also that gate dielectric 900 may comprise any appropriate dielectric, such as an oxide or a high K dielectric with, for example, a 1-2 nanometer equivalent oxide thickness (EOT).

FIGS. 9C-9E depict the semiconductor structure of FIGS. 8A & 8B after formation of a gate electrode 910 and over-etching of the gate stack down to the tunneling region 800. As illustrated, self-alignment of the horizontally-extending tunneling pocket 800 is achieved by over-etching the gate stack down through the pocket region. As illustrated in FIGS. 9D & 9E, the resultant sidewall gate is self-aligned to the horizontally-extending tunneling pocket at the foot of the sidewall gate 910. In operation, a voltage applied to the gate electrode thus modulates the Fermi level of the self-aligned tunneling region 800 to either allow or disallow carrier tunneling from source region 700 into self-aligned tunneling region 800 during ON/OFF states, respectively.

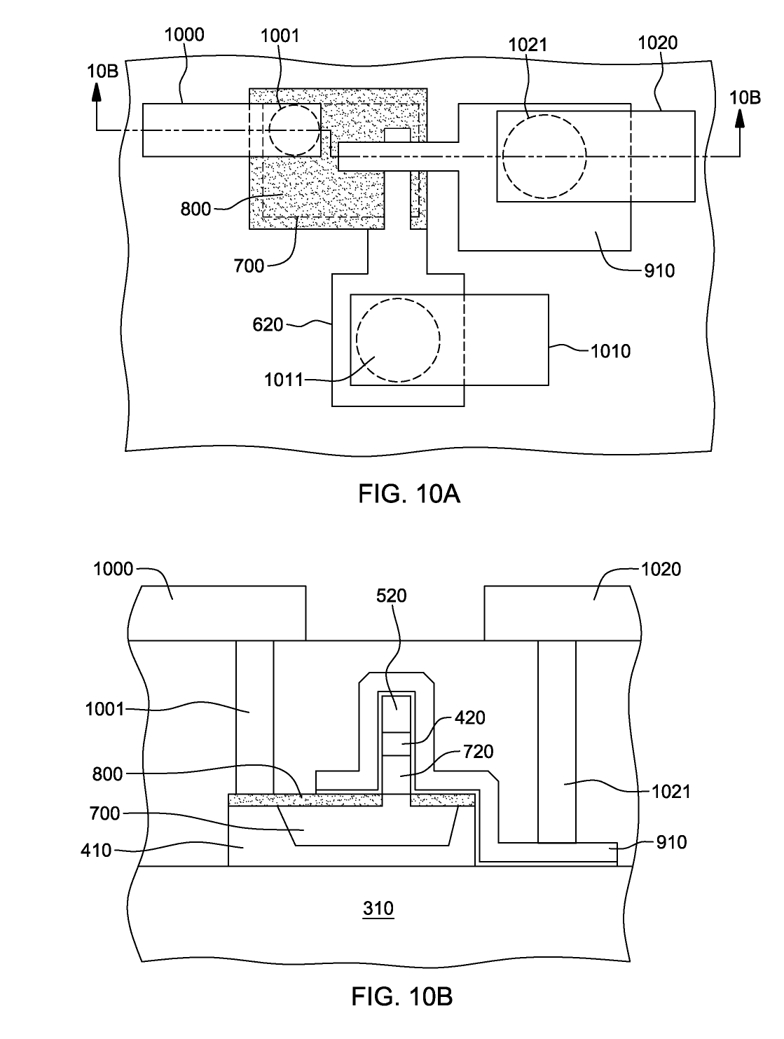

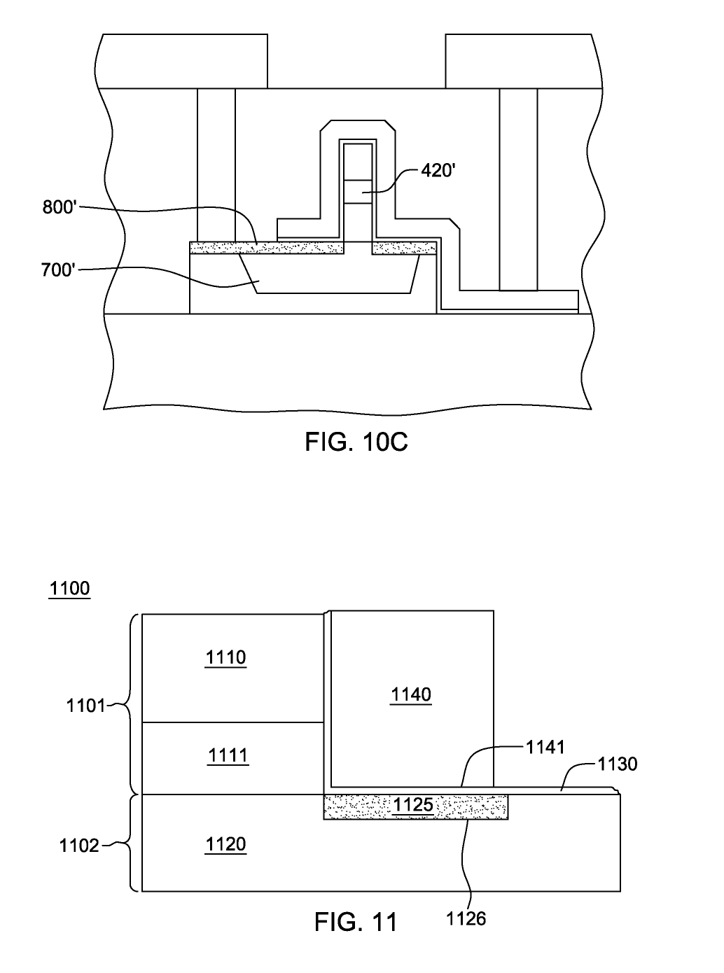

FIGS. 10A & 10B depict the semiconductor structure of FIGS. 9A & 9B after conductive plug and contact metallization to form electrical contacts to the drain, source and gate regions of the resultant tunneling field-effect transistor. As illustrated, the source contact 1000, drain contact 1010, and gate contact 1020, are respectively connected to the source, drain and gate regions via respective conductive plugs 1001, 1011, 1021. In one embodiment, the conductive plugs might comprise vertically-disposed tungsten conductors.

As illustrated in FIG. 10C, the type of dopant introduced during the source and drain region formations can be interchanged to form both n-type TFET and p-type TFET structures using the fabrication approach of FIGS. 3-10B. An alternate circuit structure is depicted in FIG. 10C, wherein the source region 420′ and drain region 700′ are interchanged from the embodiment of FIGS. 3-10B. In this implementation, the self-aligned tunneling region 800′ is disposed between the gate and drain region 700′. For example, within or over portions of the drain region between the gate region and drain region, as illustrated. Note also that masked regions using photolithography, similar to current CMOS fabrication approaches, for the various source and drain implants described herein, can be used to achieve a CMOS TFET.

To summarize, FIG. 11 depicts a simplified view of a semiconductor device 1100, in accordance with one or more aspects of the present invention. Semiconductor device 1100 comprises an angled circuit structure, such as an at least partially L-shaped, source-drain stack structure, with a first portion 1101 extending from a second portion 1102. In one example, first portion 1101 is a fin extending away from second portion 1102 at, for example, a substantially right angle to the second portion. First portion 1101 includes a source or drain region 1110 and an intrinsic region 1111, which is disposed between the source or drain region 1110 and the other of the source or drain region 1120 (disposed in the second portion 1102 of the circuit structure). A gate 1140 is spaced via a gate dielectric 1130 from the first and second portions 1101, 1102 of the angled circuit structure. Self-aligned to the fin region of the circuit structure is a tunneling region 1125 disposed, in the depicted example, within the second portion 1102, that is, within either the source or drain region 1120 of the circuit structure. In implementation, tunneling region 1125 is doped opposite to that of the source or drain region 1120 within the second portion 1102. Note that the tunneling surface 1126 (in this embodiment) is disposed parallel to and in spaced opposing relation to a control surface 1141 of gate electrode 1140. Carriers migrate from source/drain region 1120 into the self-aligned tunneling region 1125, and from there into the intrinsic region 1111 to the drain/source region 1110. Note that the gate electrode, which typically comprises a dielectric layer and a metal conductor, abuts both first region 1101 and second region 1102, whereby the regions are perpendicular or at an angle relative to each other.

As noted above, dependent upon the implementation, region 1110 may comprise a source region or a drain region, and region 1120 the other of the drain region or source region. In one embodiment, carriers tunnel from region 1120 through the self-aligned tunneling region 1125, into the intrinsic region 1111 to region 1110. By disposing gate electrode 1130 adjacent to the fin-shaped tunneling circuit structure, improved electrostatic control of the structure is obtained. Note also that providing the self-aligned tunneling region moves carrier tunneling from between regions 1120 and 1111 to between region 1120 and the tunneling region 1125. In this implementation, the control surface 1141 of gate electrode 1140 is parallel to and in spaced opposing relation to the tunneling surface (or front) 1126 between region 1120 and tunneling region 1125, as illustrated in FIG. 11.

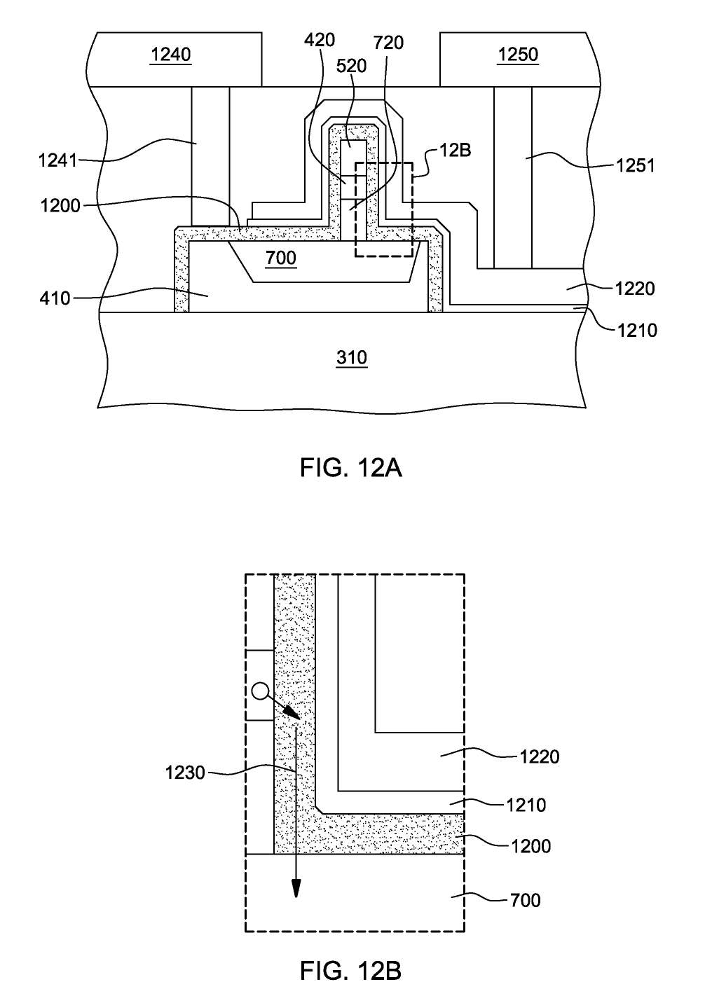

FIGS. 12A & 12B depict an alternate embodiment of a semiconductor device or tunnel field-effect transistor, in accordance with one or more aspects of the present invention. In this embodiment, a fin-shaped circuit structure is again formed, similar to that described above in connection with FIGS. 2-10C. However, rather than implanting the tunneling region into the source region, after fin and source formation, an epitaxial layer is grown to establish an at least partially vertically-extending, self-aligned tunneling region 1200. This vertically-extending tunneling region may be silicon, silicon geranium, or any other lattice-matched semiconductor which can be epitaxially grown. Operationally, the sidewall epi-layer acts as a vertical pocket for the source-drain regions. As noted above, source region 700 and drain region 420 may be interchanged.

In operation, a gate electrode 1220 will modulate across a gate dielectric 1210, the Fermi level of the self-aligned tunneling region 1200, to allow tunneling current or carrier flow 1230 (see FIG. 12B) through the tunneling region 1200 between the drain and source regions 420, 700. Note that, in this implementation, intrinsic region 720 could comprise an isolation region, since the tunneling current flows through the epitaxially-grown, self-aligned tunneling region 1200. Also shown in this figure are contact pads 1240, 1250, and respective conductors 1241, 1251 connecting the contact pads 1240, 1250 to the drain or source region 700, as well as the gate region 1220.

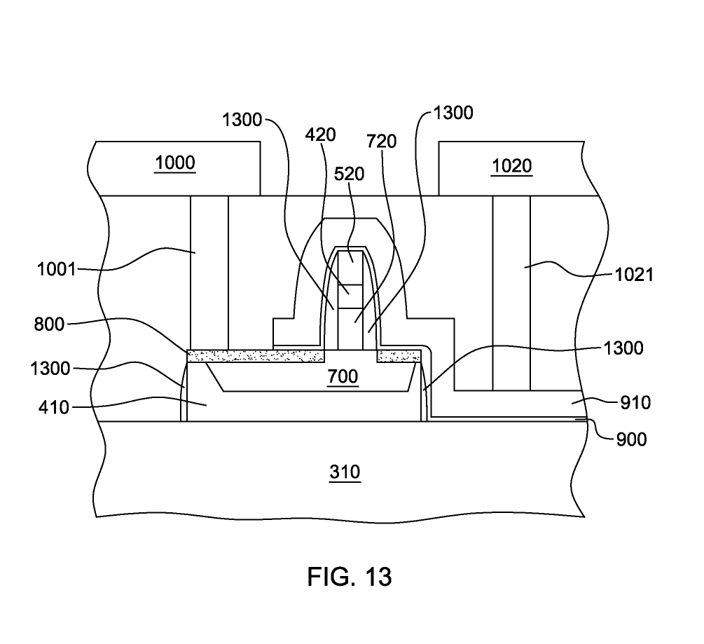

FIG. 13 illustrates another embodiment of a semiconductor device or tunnel field-effect transistors depicted in FIGS. 10A-10C. In this embodiment, the source region 420′ is assumed to be within the first or fin portion of the transistor and the drain region 700′ within the second portion of the transistor. A self-aligned spacer has been introduced after source formation. Specifically, a high-K dielectric may be deposited and plasma etched to form sidewall spacers 1300 on the fin portion of the field-effect transistor, as illustrated in FIG. 13. These self-aligned spacers are then used to selectively form the self-aligned tunneling regions (or pockets), for example, by a conformal doping or epitaxial growth, resulting in the self-aligned tunneling region being formed only on the horizontal surface of the drain region 700′. Advantageously, the configuration of FIG. 13 allows for a dual work function for channel and tunneling regions, and selective pocket formation allows for a higher tunneling current. Those skilled in the art will note that spacers 1300 facilitate creating selectively doped layers or epitaxial layers on the horizontal surfaces. In this embodiment, the tunneling region is moved slightly away from the intrinsic region, but this distance can be controlled by minimizing the sidewall spacer thickness. For example, the gate sidewall might have a thickness less than 50 angstroms. Note also that, as used herein, “self-aligned” refers to an auto-alignment of a current structure to a previous structure or to a subsequently defined structure. In the example of FIG. 13, the gate spacer is aligned to the intrinsic channel, and the self-aligned tunneling region refers to the automatic alignment of the tunneling pocket to the gate.

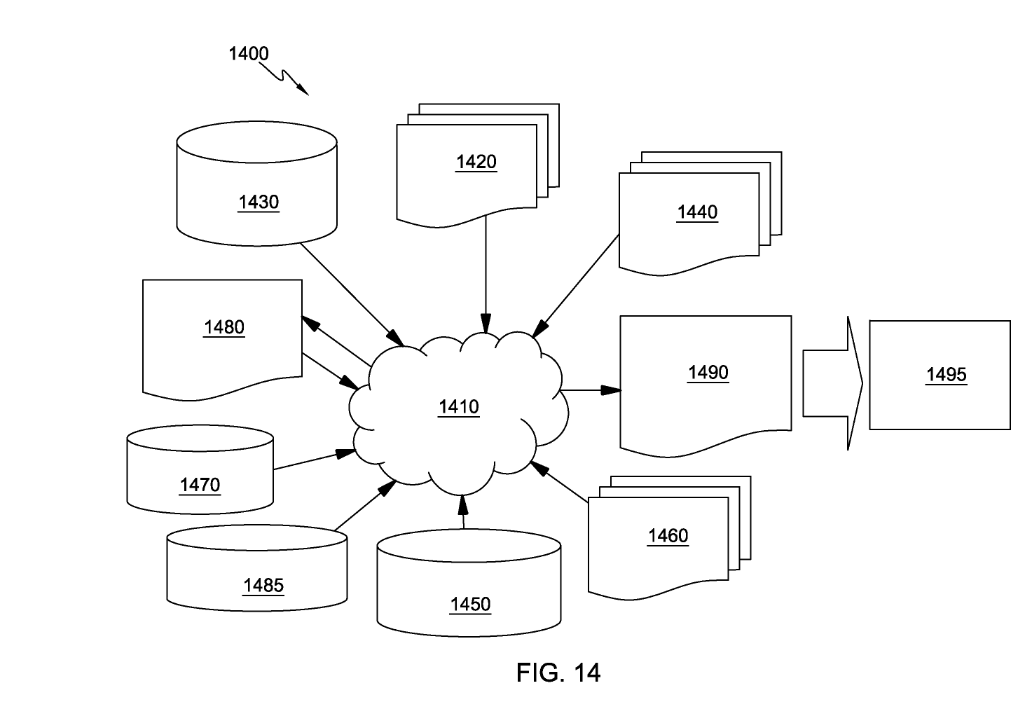

FIG. 14 depicts a block diagram of an exemplary design flow 1400 used, for example, in semiconductor circuit design, simulation, test, layout, and manufacture. Design flow 1400 includes processes and mechanisms for processing design structures or devices to generate logically or otherwise functionally-equivalent representations of the processes, design structures and/or devices described above and shown in FIGS. 2-13. The design structures and/or processes generated by design flow 1400 may be encoded on machine-readable transmission or storage media to include data and/or instructions that, when executed or otherwise processed on a data processing system, generate a logically, structurally, mechanically, or otherwise functionally-equivalent representation of hardware components, circuits, devices, or systems. Design flow 1400 may vary, depending on the type of representation being designed. For example, a design flow for building an application specific integrated circuit (ASIC) may differ from a design flow for designing a standard component, or from a design flow for instantiating the design into a programmable array, for example, a programmable gate array (PGA) or field programmable gate array (FPGA) offered by Altera®, Inc., or Xilinx®, Inc.

FIG. 14 illustrates multiple such design structures, including an input design structure 1420 that is processed by a design process 1410. Design structure 1420 may be a logical simulation design structure, generated and processed by design process 1410 to produce a logically, equivalent-functional representation of a hardware device. Design structure 1420 may also, or alternately, comprise data and/or program instruction that, when processed by design process 1410, generate a functional representation of the physical structure of a hardware device. Whether representing functional and/or structural design features, design structure 1420 may be generated using electronic computer-aided design (ECAD), such as implemented by a core developer/designer. When encoded on a machine-readable data transmission, gate array, or storage medium, design structure 1420 may be accessed and processed by one or more hardware and/or software modules within design process 1410 to simulate or otherwise functionally represent an electronic component, circuit, electronic or logic module, apparatus, device or system, such as those shown in FIGS. 2-13. As such, design structure 1420 may comprise files or other data structures, including human and/or machine-readable source code, compiled structures, and computer-executable code structures that, when processed by a design or simulation data processing system, functionally simulate or otherwise represent circuits or other levels of hardware logic design. Such data structures may include hardware-description language (HDL), design entities, or other data structures conforming to and/or compatible with lower-level HDL design languages, such as Verilog and VHDL, and/or higher-level design languages, such as C or C++.

Design process 1410 may employ and incorporate hardware and/or software modules for synthesizing, translating, or otherwise processing a design/simulation functional equivalent of the components, circuits, devices or logic structures shown in FIGS. 2-13 to generate a netlist 1480, which may contain design structures, such as design structure 1420. Netlist 1480 may comprise, for example, compiled or otherwise processed data structures representing a list of wires, discrete components, logic gates, control circuits, I/O devices, models, etc. that describes the connections to other elements and circuits in an integrated circuit design. Netlist 1480 may be synthesized using an interactive process in which netlist 1480 is re-synthesized one or more times, depending on design specifications and parameters for the device. As with other design structure types described herein, netlist 1480 may be recorded on a machine-readable data storage medium, or programmed into a programmable gate array. The medium may be a non-volatile storage medium, such as a magnetic or optical disk drive, a programmable gate array, a compact flash, or other flash memory. Additionally, or in the alternative, the medium may be a system cache memory, buffer space, or electrically or optically conductive devices and materials on which data packets may be transmitted and intermediately stored via the Internet, or other networking suitable means.

Design process 1410 may include hardware and software modules for processing a variety of input data structure types, including netlist 1480. Such data structure types may reside, for example, within library elements 1430 and include a set of commonly used elements, circuits, and devices, including modules, layouts, and symbolic representations, for a given manufacturing technology (e.g., different technology nodes, 32 nm, 45 nm, etc.). The data structure types may further include design specifications 1440, characterization data 1450, verification data 1460, design rules 1470, and test data files 1485, which may include input test patterns, output test results, and other testing information. Design process 1410 may further include, for example, standard mechanical design processes, such as stress analysis, thermal analysis, mechanical event simulation, process simulations for operations, such as casting, molding, and die press forming, etc. One of ordinary skill in the art of mechanical design can appreciate the extent of possible mechanical design tools and applications used in design process 1410, without deviating from the scope and spirit of the invention. Design process 1410 may also include modules for performing standard circuit design processes, such as timing analysis, verification, design rule checking, place and route operations, etc.

Design process 1410 employs and incorporates logical and physical design tools, such as HDL, compilers and simulation module build tools to process design structure 1420 together with some or all of the depicted supporting data structures, along with any additional mechanical design of data (if applicable), to generate a second design structure 1490. Design structure 1490 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 1420, design structure 1490 may comprise one or more files, data structures, or other computer-encoded data or instructions that reside on transmission or data storage media, and that when processed by an ECAD system, generate a logically or otherwise functionally-equivalent form of one or more of the embodiments of the invention. In one embodiment, design structure 1490 may comprise a compiled, executable HDL simulation model that functionally simulates the processes and devices shown in FIGS. 2-13.

Design structure 1490 may also employ a data format used for the exchange of layout data of integrated circuits and/or symbolic data format (e.g., information stored in a GDSII (GDS2), GL1, OASIS, map files, or any other suitable format for storing such design data structures). Design structure 1490 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce devices or structures, such as described above and shown in FIGS. 2-13. Design structure 1490 may then proceed to stage 1495, where, for example, design structure 1490 proceeds to tape-out, is released to manufacturing, is released to a mask house, is sent to another design house, is sent back to the customer, etc.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention.

What is claimed is:

1. A semiconductor device comprising:
a gated circuit structure, the gated circuit structure comprising:
an angled circuit structure, the angled circuit structure being at least partially angled in cross-sectional elevation, and comprising a first portion and a second portion, the first portion of the angled circuit structure extending away from the second portion of the angled circuit structure;
a gate electrode for gating the angled circuit structure; and
a self-aligned tunneling region, the self-aligned tunneling region being self-aligned to at least a portion of the angled circuit structure and extending between the gate electrode and at least one of the first portion or the second portion of the angled circuit structure, and a tunneling surface of the self-aligned tunneling region being disposed at least partially parallel to a surface of the gate electrode.

2. The semiconductor device of claim 1, wherein the self-aligned tunneling region comprises a horizontally-extending tunneling pocket disposed at least partially below the gate electrode, the horizontally-extending tunneling pocket being at least one of disposed within the second portion of the angled circuit structure or over the second portion of the angled circuit structure, between the gate electrode and the second portion of the angled circuit structure.

3. The semiconductor device of claim 1, wherein the self-aligned tunneling region comprises a vertically-extending tunneling pocket disposed over at least a portion of the first portion of the angled circuit structure, between the first portion of the angled circuit structure and the gate electrode.

4. The semiconductor device of claim 1, wherein the semiconductor device comprises a transistor, the transistor comprising the first portion and the second portion of the angled circuit structure, and the angled circuit structure being a finned circuit structure, the first portion of the angled circuit structure defining a fin of the finned circuit structure.

5. The semiconductor device of claim 4, wherein the first portion of the angled circuit structure comprises one of a source region or a drain region, and the second portion of the angled circuit structure comprises the other of the source region or the drain region.

6. The semiconductor device of claim 1, wherein the self-aligned tunneling region has a thickness in a direction perpendicular to the surface of the gate electrode less than or equal to 10 nanometers.

7. The semiconductor device of claim 1, wherein the self-aligned tunneling region is self-aligned to the first portion of the angled circuit structure.

8. The semiconductor device of claim 7, wherein the gate electrode is also self-aligned to the first portion of the angled circuit structure.

9. A tunnel field-effect transistor comprising:
a source-drain stack structure comprising a source region and a drain region, the source-drain stack structure being at least partially angled in cross-sectional elevation, and the source-drain stack structure comprising a first portion and a second portion, the first portion of the source-drain stack structure extending away from the second portion of the source-drain stack structure at an angle, the source region residing in one of the first portion or the second portion, and the drain region residing in the other of the first portion or the second portion;
a gate electrode for gating the source-drain stack structure; and
a self-aligned tunneling region, the self-aligned tunneling region being self-aligned to at least a portion of the source-drain stack structure and extending between the gate electrode and at least one of the first portion or the second portion of the source-drain stack structure, and a tunneling surface of the self-aligned tunneling region being disposed at least partially parallel to a surface of the gate electrode.

10. The tunnel field-effect transistor of claim 9, wherein the self-aligned tunneling region comprises a horizontally-extending tunneling pocket disposed at least partially below the gate electrode, the horizontally-extending tunneling pocket being at least one of disposed within the second portion of the source-drain stack structure or over the second portion of the source-drain stack structure, between the gate electrode and the second portion of the source-drain stack structure.

11. The tunnel field-effect transistor of claim 10, wherein the source region is disposed in the second portion of the source-drain stack structure, the drain region is disposed in the first portion of the source-drain stack structure, and the first portion of the source-drain stack structure further includes an intrinsic region, the intrinsic region being disposed between the drain region and the source region.

12. The tunnel field-effect transistor of claim 9, wherein the self-aligned tunneling region comprises a vertically-extending tunneling pocket disposed over at least a portion of the first portion of the source-drain stack structure, between the first portion of the source-drain stack structure and the gate electrode.

13. The tunnel field-effect transistor of claim 9, wherein the self-aligned tunneling region has a thickness in a direction perpendicular to the surface of the gate electrode less than or equal to 10 nanometers.

14. The tunnel field-effect transistor of claim 9, wherein the self-aligned tunneling region is self-aligned to the first portion of the source-drain stack structure, and the source-drain stack structure is a finned circuit structure, the first portion of the source-drain stack structure defining a fin of the finned circuit structure.

15. The tunnel field-effect transistor of claim 14, wherein the gate electrode is also self-aligned to the first portion of the source-drain stack structure.

16. A method of fabricating a semiconductor device comprising:
fabricating a gated circuit structure, wherein fabricating the gated circuit structure comprises:
providing an angled circuit structure, the angled circuit structure being at least partially angled in cross-sectional elevation, and comprising a first portion and a second portion, the first portion of the angled circuit structure extending away from the second portion of the angled circuit structure;
providing a self-aligned tunneling region and a gate electrode for the angled circuit structure, the self-aligned tunneling region being self-aligned to at least a portion of the angled circuit structure and extending between the gate electrode and at least one of the first portion or the second portion of the angled circuit structure, and a tunneling surface of the self-aligned tunneling region being at least partially disposed parallel to a surface of the gate electrode.

17. The method of claim 16, wherein the self-aligned tunneling region comprises a horizontally-extending tunneling pocket disposed at least partially below the gate electrode, the horizontally-extending tunneling pocket being at least one of disposed within the second portion of the angled circuit structure or over the second portion of the angled circuit structure, between the gate electrode and the second portion of the angled circuit structure.

18. The method of claim 16, wherein the self-aligned tunneling region comprises a vertically-extending tunneling pocket disposed over at least a portion of the first portion of the angled circuit structure, between the first portion of the angled circuit structure and the gate electrode.

19. The method of claim 16, wherein the self-aligned tunneling region is self-aligned to the first portion of the angled circuit structure.

20. The method of claim 19, wherein the gate electrode is also self-aligned to the first portion of the angled circuit structure.
